(19) United States
(12) Patent Application Publication
(10) Pub. No.: US 2006/0087020 A1
(43) Pub. Date: Apr. 27, 2006

(54) Semiconductor device and method for producing the same

(75) Inventors: Koichi Hirano, Hirakata-shi (JP); Seiichi Nakatani, Hirakata-shi (JP); Tsukasa Shiraishi, Takatsuki-shi (JP); Yoshitake Hayashi, Kawachinagano-shi (JP)

Correspondence Address: HAMRE, SCHUMANN, MUELLER & LARSON P.C., P.O. BOX 2902-0902, MINNEAPOLIS, MN, 55402, US

(73) Assignee: MATSUSHITA ELECTRIC INDUSTRIAL CO., LTD., KADOMA-SHI (JP)

(21) Appl. No.: 11/254,379

(22) Filed: Oct. 20, 2005

(30) Foreign Application Priority Data
Oct. 22, 2004 (JP) 2004-308438

(51) Int. Cl. H01L 23/02

(52) U.S. Cl. 257/686

(57) ABSTRACT

In a semiconductor device, circuit boards are connected electrically to each other by via-conductors that penetrate sheet members, semiconductor elements arranged between substrates are contained in element-containing portions formed on the sheet members, and a low-elastic material whose elastic modulus is lower than the elastic modulus of the thermosetting resin composition of the sheet members is filled in the space between the semiconductor elements contained in the element-containing portions and the substrates opposing surfaces opposite to the mounting surfaces of the semiconductor elements. Thereby, a semiconductor device resistant to warping and deformation and having a high mounting reliability is provided.

### BACKGROUND OF THE INVENTION

1. Field of the Invention

The present invention relates to a semiconductor device used in an electric/electronic apparatus, and a method for producing the same.

2. Description of Related Art

Due to an accelerated tendency toward miniaturization of portable electronic apparatuses, there is a keen demand for downsizing and high-density mounting of electronic parts to be incorporated. Among various electronic parts, semiconductor devices having multi-staged structures of laminating circuit boards including semiconductor elements have been proposed particularly.

For an example of such semiconductor devices having multi-staged structures, JP H10-135267A proposes a semiconductor device including circuit boards that are electrically connected to each other with solder balls.

However, since such a semiconductor device is formed by laminating a plurality of packaged circuit boards, the overall thickness of the semiconductor device will be increased. Moreover, when the connection pitch is set to be 0.5 mm or less for the purpose of downsizing the semiconductor device, a short circuit may occur between solder balls. Furthermore, since the circuit boards are required to be flat and parallel to each other for solder connection, there are considerable limitations on the stiffness and thickness of the circuit boards.

For high-density mounting and reduction in thickness of the semiconductor device, JP2003-218273A proposes, for example, a semiconductor device that is formed by alternately laminating, through adhesive layers, circuit boards on which semiconductor elements are mounted and interlayer members having cavities for containing the semiconductor elements, and embedding the semiconductor elements in the cavities by heat press. In the semiconductor device, the circuit boards are electrically connected to each other through via-conductors formed in the interlayer members.

JP2002-261449A proposes a member-containing module with built-in components. The module contains semiconductor elements within a core layer as an electrical insulating layer for the purpose of realizing downsizing and reduction in thickness of electronic parts and improvement of the functions.

For reducing thickness of a laminated semiconductor device, both the thickness of the semiconductor elements and substrates on which the semiconductor elements are mounted must be reduced. Recently, the thickness of a substrate for mounting a semiconductor is reduced further; particularly, the thickness for a double-sided circuit board is reduced to 0.1 mm or less, and for a four-layered circuit board, 0.2 mm or less. According to the above-mentioned JP2003-218273A, a semiconductor element mounted on a resin substrate is embedded in a cavity. However, since the cavity is formed in the vicinity of the semiconductor element, the stiffness of the circuit board will deteriorate when a thin resin substrate is used, and thus warping or deformation may occur easily. Therefore, according to the above-mentioned configuration, mounting reliability of the semiconductor element and mounting reliability of the semiconductor device with respect to a mother board may deteriorate.

According to the above-mentioned JP2002-261449A, the semiconductor element is embedded entirely in a core layer. This configuration is excellent in that heat dissipation of the built-in semiconductor element will be improved and deformation of the entire apparatus is unlikely to occur, so the flatness will be improved. However, since the semiconductor element is in a built-in state in the core layer, thermal stress occurring at the joint between the semiconductor element and the substrate will be increased, and thus mounting reliability in a heat cycle test or a reflow test after moisture absorption will deteriorate considerably. When the core layer is made of a low-elastic material for relieving the thermal stress, the strength of the core layer will deteriorate so that warping and deformation may occur easily.

### SUMMARY OF THE INVENTION

Therefore, with the foregoing in mind, it is an object of the present invention to provide a semiconductor device that is unlikely to cause warping and deformation and has high mounting reliability, and a method for producing the same.

A first semiconductor device of the present invention is a semiconductor device having a plurality of circuit boards including substrates and semiconductor elements mounted on the substrates, the circuit boards being bonded to each other through sheet members of a thermosetting resin composition, wherein

the plural circuit boards are connected electrically to each other by via-conductors penetrating the sheet members,

the semiconductor elements arranged between the substrates are contained in element-containing portions formed in the sheet members, and

a low-elastic material whose elastic modulus is lower than the elastic modulus of the thermosetting resin composition is filled in the space between each of the semiconductor elements contained in each of the element-containing portions and the substrate opposing the surface opposite to the mounting surface of the semiconductor element.

A second semiconductor device of the present invention is a semiconductor device having a plurality of circuit boards including substrates and semiconductor elements mounted on the substrates, the circuit boards being bonded to each other through sheet members of a thermosetting resin composition, wherein

the plural circuit boards are connected electrically to each other by via-conductors penetrating the sheet members,

the semiconductor elements arranged between the substrates are contained in an element-containing portion formed on the sheet member,

at least one of the semiconductor elements to be contained in the element-containing portion is mounted on each of the two substrates covering the element-containing portion,

at least one pair of the semiconductor elements are contained facing each other in the element-containing portion, and

a low-elastic material whose elastic modulus is lower than the elastic modulus of the thermosetting resin composition is filled in the space between surfaces of the pair of the semiconductor elements opposite to the mounting surfaces.

A method for producing a semiconductor device according to the present invention includes the steps of:

mounting semiconductor elements on substrates so as to form circuit boards,

forming element-containing portions for containing the semiconductor elements and through holes to be filled with a conductor on sheet members of an uncured thermosetting resin composition,

filling a conductor in the through holes,

positioning the circuit boards and the sheet members and laminating alternately, and applying heat and pressure while injecting a low-elastic material into the element-containing portions, where the elastic modulus of the low-elastic material is lower than the elastic modulus of the thermosetting resin composition, thereby simultaneously curing the thermosetting resin composition and the low-elastic material so as to incorporate, and electrically connecting the plural circuit boards.

### BRIEF DESCRIPTION OF THE DRAWINGS

FIG. 1 is a cross-sectional view showing a semiconductor device according to Embodiment 1 of the present invention.

FIGS. 2A-2H are cross-sectional views for showing process steps for producing a semiconductor device according to Embodiment 1 of the present invention.

FIG. 3 is a cross-sectional view showing a semiconductor device according to Embodiment 2 of the present invention.

FIGS. 4A-4F are cross-sectional views for showing process steps for producing a semiconductor device according to Embodiment 2 of the present invention.

FIG. 5 is a cross-sectional view showing a semiconductor device according to Embodiment 3 of the present invention.

FIGS. 6A and 6B are cross-sectional views for showing process steps for producing a semiconductor device according to Embodiment 3 of the present invention.

FIG. 7 is a cross-sectional view showing a semiconductor device according to Embodiment 4 of the present invention.

FIG. 8 is a cross-sectional view showing a semiconductor device according to Embodiment 5 of the present invention.

FIGS. 9A-9D are cross-sectional views for showing process steps for producing a semiconductor device according to Embodiment 5 of the present invention.

FIG. 10 is a cross-sectional view showing a semiconductor device according to Embodiment 6 of the present invention.

FIG. 11 is a cross-sectional view showing a semiconductor device according to Embodiment 7 of the present invention.

FIG. 12 is a cross-sectional view showing a semiconductor device according to Embodiment 8 of the present invention.

FIGS. 13A-13D are cross-sectional views for showing process steps for producing a semiconductor device according to Embodiment 8 of the present invention.

FIG. 14 is a cross-sectional view showing a semiconductor device according to Embodiment 9 of the present invention.

FIG. 15 is a cross-sectional view showing a semiconductor device according to Embodiment 10 of the present invention.

### DETAILED DESCRIPTION OF THE INVENTION

A first semiconductor device of the present invention has a plurality of circuit boards including substrates and semiconductor elements mounted on the substrates, where the circuit boards are bonded to each other through sheet members of a thermosetting resin composition. The circuit boards are connected electrically to each other with via-conductors penetrating the sheet members, and the semiconductor elements arranged between the substrates are contained in element-containing portions formed on the sheet members. The thermosetting resin composition includes at least a thermosetting resin such as epoxy resin. For the via-conductor, an inner via that allows a high-density mounting is used preferably. Alternatively, a penetration conductor formed by plating can be used.

In the first semiconductor device of the present invention, a low-elastic material whose elastic modulus is lower than the elastic modulus of the thermosetting resin composition is filled in the space between a semiconductor element contained in an element-containing portion and the substrate opposing a surface (hereinafter, this may be referred to as ‘upper surface’) opposite to the mounting surface of the semiconductor element. Here, the term “a mounting surface of a semiconductor element” denotes either the upper or lower main surface of the semiconductor element, which faces the substrate on which the semiconductor element is mounted.

In the first semiconductor device, the via-conductors are held by the sheet members of the thermosetting resin composition, and a low-elastic material whose elastic modulus is lower than the elastic modulus of the thermosetting resin composition is filled in the space between the semiconductor elements and the substrates opposing upper surfaces of the semiconductor elements. Therefore, warping and deformation will be unlikely to occur even when thin substrates or thin semiconductor elements are used. Moreover, since the low-elastic material serves to decrease the thermal stress applied to the space between the semiconductor elements and the substrates, the mounting reliability can be improved. Furthermore, since the low-elastic material serves to dissipate quickly heat generated at the semiconductor elements to the outside. In this specification, the term “elastic modulus” denotes a reserved elastic modulus at 25° C., and it can be measured by a method corresponding to JIS K7244. The elastic modulus of the low-elastic material is lower, for example, by at least 1000 MPa in comparison with the elastic modulus of the thermosetting resin composition.

In the first semiconductor device of the present invention, the semiconductor elements contained in the element-containing portions can be sealed with the low-elastic material in order to prevent degradation of the semiconductor elements.

In the first semiconductor device of the present invention, the cavities in the element-containing portions can be filled with the low-elastic material in order to prevent deformation caused by the presence of the cavities, thereby providing a semiconductor device having a high mounting reliability.

In the first semiconductor device of the present invention, at least one of the semiconductor elements to be contained in an element-containing portion can be mounted on each of two substrates for covering the element-containing portion. Accordingly, a plurality of semiconductor elements can be contained in an element-containing portion so as to reduce thickness of the semiconductor device.

It is preferable in the first semiconductor device of the present invention that at least one of the semiconductor elements is flip-chip mounted on the substrate. According to this configuration, a reduction in thickness and high-density mounting of the semiconductor elements can be performed easily.

Next, a second semiconductor device of the present invention will be described below. Components identical to those of the above-mentioned first semiconductor device may be omitted from the following description.

The second semiconductor device of the present invention has a plurality of circuit boards including substrates and semiconductor elements mounted on the substrates, and the circuit boards are bonded to each other through sheet members of a thermosetting resin composition. The circuit boards are connected electrically to each other with via-conductors penetrating the sheet members, and the semiconductor elements between the substrates are contained in the element-containing portions formed on the sheet members.

In the second semiconductor device of the present invention, at least one of the semiconductor elements to be contained in the element-containing portion is mounted on each of two substrates for covering an element-containing portion, where at least one pair of the semiconductor elements are contained facing each other in the element-containing portion, and a low-elastic material whose elastic modulus is lower than the elastic modulus of the thermosetting resin composition is used to fill the space the pair of the semiconductor elements.

In the second semiconductor device of the present invention, the sheet members of the thermosetting resin composition hold the via-conductors, and at the same time, a low-elastic material whose elastic modulus is lower than the elastic modulus of the thermosetting resin composition is used to fill the space between the pair of the semiconductor elements. Therefore, even when a thin substrate or a thin semiconductor element is used, warping and deformation rarely occurs, and the mounting reliability will be improved. Furthermore, since at least one pair of semiconductor elements are contained facing each other in the element-containing portion, the surface area of the semiconductor device can be reduced easily.

In the second semiconductor device of the present invention, the cavities in the element-containing portion can be filled with the low-elastic material. Accordingly, deformation caused by the cavity can be prevented, and furthermore, thermal stress that will be applied to the space between the semiconductor element and the substrate by the low-elastic material can be decreased, and thereby the mounting reliability will be improved further. Furthermore, the low-elastic material serves to dissipate heat generated at the semiconductor elements to the outside quickly.

It is preferable in each of the above-mentioned semiconductor devices that a moisture-absorbing filler is mixed in the low-elastic material in order to prevent degradation caused by moisture of the semiconductor device.

It is preferable in each of the above-mentioned semiconductor devices that thermo-conductive filler is mixed in the low-elastic material in order to dissipate heat generated at the semiconductor elements to the outside more efficiently.

It is preferable in each of the above-mentioned semiconductor devices that the elastic modulus of the low-elastic material is 1 to 1000 MPa, and more preferably, 50 to 500 MPa. An elastic modulus higher than 1000 MPa is not so different from the elastic modulus of the thermosetting resin composition, and the above-mentioned effect of decreasing the thermal stress may not be obtained. When the elastic modulus is lower than 1 MPa, the above-mentioned effect of decreasing thermal stress can be obtained, but warping and deformation may occur.

In a preferred embodiment for each of the semiconductor devices, the thermosetting resin composition contains an inorganic filler in an amount of 70 to 95 mass %. In this case, the coefficient of linear expansion of the thermosetting resin composition gets closer to that of the via-conductors, and thus the connection reliability of the via-conductors is improved. Moreover, the thermal conductivity of the thermosetting resin composition becomes higher, and thereby heat generated at the semiconductor elements can be dissipated efficiently.

In a preferred embodiment for each of the semiconductor devices, the thermosetting resin composition contains a reinforcer in an amount of 15 to 50 mass %. In this case, warping and deformation in the sheet member of the thermosetting resin composition can be prevented efficiently.

A method for producing a semiconductor device of the present invention includes: forming circuit boards by mounting semiconductor elements on substrates, forming element-containing portions for containing the semiconductor elements on sheet members made of an uncured thermosetting resin composition and through holes to be filled later with a conductor. After positioning the circuit boards and the sheet members and laminating alternately, the laminate is subjected to heat and pressure while a low-elastic material whose elastic modulus is lower than the elastic modulus of the thermosetting resin composition is injected into the element-containing portions so as to cure and integrate simultaneously the thermosetting resin composition and the low-elastic material, and at the same time, the plurality of circuit boards are connected electrically to each other. Thereby, the above-mentioned semiconductor device can be formed easily.

It is preferable in the method for producing a semiconductor device of the present invention that through holes are formed in the circuit boards, specifically in the vicinity of the areas for mounting the semiconductor elements, before laminating the circuit boards and the sheet members, and the low-elastic material is injected into the element-containing portions from the through holes. In this manner, the low-elastic material can be injected into the element-containing portions with certainty.

Hereinafter, the present invention will be described by way of illustrative embodiments with reference to the drawings. It should be noted that in the description of the embodiments, similar parts are given similar symbols, and duplicate description may be omitted.

### EMBODIMENT 1

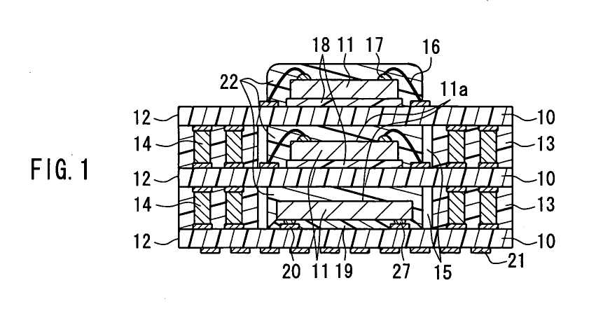

FIG. 1 is a cross-sectional view showing a semiconductor device according to Embodiment 1 of the present invention. As shown in FIG. 1, a semiconductor device according to Embodiment 1 has three circuit boards 12 including substrates 10 and semiconductor elements 11 mounted on the substrates 10, and these three circuit boards 12 are bonded to each other through sheet members 13 made of a thermosetting resin composition. The three circuit boards 12 are connected electrically with via-conductors 14 penetrating the sheet members 13, and the semiconductor elements 11 arranged between the substrates 10 are contained in element-containing portions 15. In FIG. 1, 16 denotes a wire, 17 denotes an electrode, 18 denotes a die-bond agent, 19 denotes an underfill, 20 denotes an element-mounting electrode, 21 denotes an external connection electrode, and 27 denotes a gold bump.

There is no particular limitation for the semiconductor elements 11, but semiconductor elements made of, for example, Si, GaAs, GaAlAs, SiGe or the like can be used. For the substrates 10, for example, multi-layered ceramic substrates comprising alumina and glass-alumina, and resin substrates comprising glass-epoxy, aramid-epoxy and the like, can be used. In light of the need for reduction of weight and cost, a resin substrate is preferred.

It is preferable that the thickness of the semiconductor element 11 is not more than 100 μm. It is also preferable that the thickness of the substrate 10 is not more than 200 μm, and more preferably, not more than 100 μm, so that the thickness of the semiconductor device can be decreased easily.

For the main component of the thermosetting resin composition, a thermosetting resin such as epoxy resin, phenol resin, modified polyimide resin, polyamideimide resin, isocyanate resin and the like can be used. These resins have excellent durability due to the excellent heat resistance.

It is further preferable that the above-mentioned thermosetting resin composition contains an inorganic filler. Since the coefficient of linear expansion of the thermosetting resin composition can be lowered by adding such an inorganic filler, the dimensional change caused by the application of thermal stress can be decreased. For the inorganic filler, for example, a filler made of Al₂O₃, SiO₂, SiC, AlN, BN, MgO or Si₃N₄ is used preferably. Particularly, when an inorganic filler made of Al₂O₃, SiO₂, SiC or AlN is used, the thermal conductivity of the thermosetting resin composition is improved, and heat dissipation from the semiconductor elements is increased. Two or more kinds of inorganic fillers can be mixed in use. For the inorganic filler, particles having a diameter of 0.1 to 100 μm can be used preferably. It is preferable that the thermosetting resin composition is a mixture of an inorganic filler of 70 to 95 mass %, and a thermosetting resin of 5 to 30 mass %. When the content of the thermosetting resin is less than 70 mass %, the thermal conductivity of the thermosetting resin will not rise in comparison with a case of using the thermosetting resin alone, and the dissipation effect may not be obtained. When the content of the inorganic filler exceeds 95 mass %, mixing of the inorganic filler will be difficult, and the electric insulation of the sheet members 13 can deteriorate.

It is preferable that the above-mentioned thermosetting resin composition includes a reinforcer. A reinforcer included in the thermosetting resin composition can serve to prevent the via-conductors from flowing to cause connection failure of the via-conductors during lamination-integration in the below-mentioned process step of producing a semiconductor device. For the reinforcer, for example, a glass cloth, a glass nonwoven fabric, an aramid nonwoven fabric, an aramid film, a ceramic nonwoven fabric or the like can be used.

The thermosetting resin composition can include further an additive such as a curing agent, a curing catalyst, a coupling agent, a surfactant, and a coloring agent.

For the via-conductors 14, for example, a mixture containing at least a conductive powder and a thermosetting resin can be used. For the conductive powder, for example, a powder of a metal based on Ag, Cu, Au, Ni, Pd or Pt, or an alloy of these metals can be used. Particularly, a powder of Ag or Cu, or a powder of alloy containing Ag or Cu is used preferably. For the thermosetting resin, for example, epoxy resin, phenol resin, isocyanate resin, polyamide resin, and polyamideimide resin can be used. These resins can be used preferably because of their excellent durability.

A material for the underfill 19 can be selected suitably corresponding to the semiconductor mounting method. For example, a mixture based on a thermosetting resin and a silica filler can be used. For example, the underfill 19 has an elastic modulus of about 0.5 to about 15 GPa. The element-mounting electrode 20 is used suitably as required for extracting signals from the semiconductor elements 11, and an electrode made of gold or the like can be used for this purpose.

The size of the element-containing portions 15 can be determined suitably corresponding to the size of the semiconductor elements 11 to be contained. For example, space between a semiconductor element 11 and a substrate 10 can be in a range of 30 μm to 200 μm, and space between the semiconductor element 11 and a sheet member 13 can be in a range of 50 μm to 2 mm.

For the wire 16, for example, a metal wire of gold or aluminum can be used. Connection of semiconductors with the wire 16 can be carried out by using an ordinary wire bonder. For the material of the electrode 17, for example, aluminum, and alloy of aluminum and copper can be used. For the die-bond agent 18, a commonly available die-bond agent can be used.

In the semiconductor device according to Embodiment 1, a low-elastic material 22 whose elastic modulus is lower than that of the thermosetting resin composition is filled in the space between a semiconductor element 11 contained in an element-containing portion 15 and the substrate 10 opposing the upper surface 11a of the semiconductor element 11. Thereby, even when a substrate 10 having a thickness of not more than 60 μm or a semiconductor element 11 having a thickness of not more than 100 μm is used, warping and deformation will be unlikely to occur. Moreover, since the thermal stress applied to the space between the upper surface 11a of the semiconductor element 11 and the substrate 10 can be decreased, the mounting reliability will be improved. Furthermore, the low-elastic material 22 serves to dissipate heat generated at the semiconductor element 11 to the outside quickly. In the semiconductor device according to Embodiment 1, the respective semiconductor elements 11 are sealed with the low-elastic material 22. Thereby, degradation of the respective semiconductor elements 11 can be prevented. The method for sealing the semiconductor elements 11 with the low-elastic material 22 is not limited particularly, but potting or a method of using a dispenser can be used for this purpose. At this time, it is preferable that the low-elastic material 22 is cured, and the curing method can be selected from, for example, thermosetting, ultraviolet curing, and curing by moisture absorption.

For the low-elastic material 22, materials that have relatively high heat resistance can be used, and the examples include silicone resin, silicone rubber, urethane rubber, fluorine rubber, silicone gel and a mixture of any of the materials and a thermosetting resin. Among them, silicone resin and silicone gel are preferred from a viewpoint of the heat resistance.

It is preferable that a moisture-absorbing filler is added to the low-elastic material 22. By adding a moisture-absorbing filler, moisture entering from the exterior can be captured, and thus the connection reliability with respect to the semiconductor element connection portion or the via-conductor connection portion can be improved. An example of the moisture-absorbing filler that can be used here will have 100 mass parts when kept untreated for 72 hours under an atmosphere of 25° C. and a humidity of 30%. The filler will have 110 mass parts when kept untreated for 72 hours under an atmosphere of 25° C. and a humidity of 85%. Specific examples of the moisture-absorbing filler include silica gel, zeolite, potassium titanate, sepiolite and the like. The content of the moisture-absorbing filler in the low-elastic material is, for example, in a range of about 20 to about 60 mass %.

It is preferable that a thermo-conductive filler is added to the low-elastic material 22. Since the thermal conductivity of the low-elastic material 22 can be improved by adding the thermo-conductive filler, heat generated at the semiconductor elements can be dissipated to the outside quickly. For the thermo-conductive filler, for example, Al₂O₃, BN, MgO, AlN, and SiO₂ can be used. The content of the thermo-conductive filler in the low-elastic material is, for example, in a range of about 30 to about 70 mass %.

In the semiconductor device according to Embodiment 1, a semiconductor element 11 is flip-chip mounted on the upper surface of a bottom substrate 10 at the element-containing portion 15 side, while the remaining semiconductor elements 11 are mounted on the remaining substrates 10 by wire-bonding. Further, an external connection electrode 21 is provided on the bottom substrate 10, specifically, on a surface opposite to the element-containing portion 15 side. Thereby, a semiconductor element 11 having a number of electrodes is flip-chip mounted on the bottom substrate 10 so as to improve the mounting efficiency. Furthermore, by wire-bond mounting another semiconductor element 11 having a relatively small number of electrodes on another substrate 10, the cost for producing the semiconductor device can be decreased. In addition, since a semiconductor element 11 having a small number of connection points is arranged on the top, the number of lands can be decreased, and thereby the surface area of the semiconductor device can be reduced easily. An example of such a semiconductor device is formed by combining a logic semiconductor element typically having a number of electrodes and a memory semiconductor element having a relatively small number of electrodes.

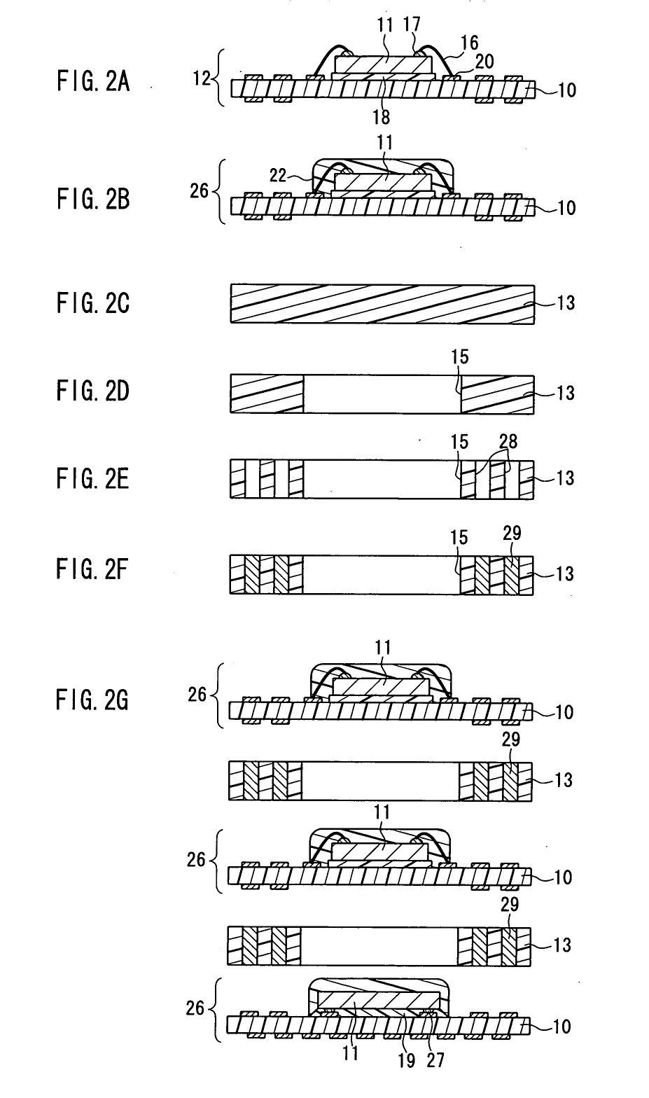

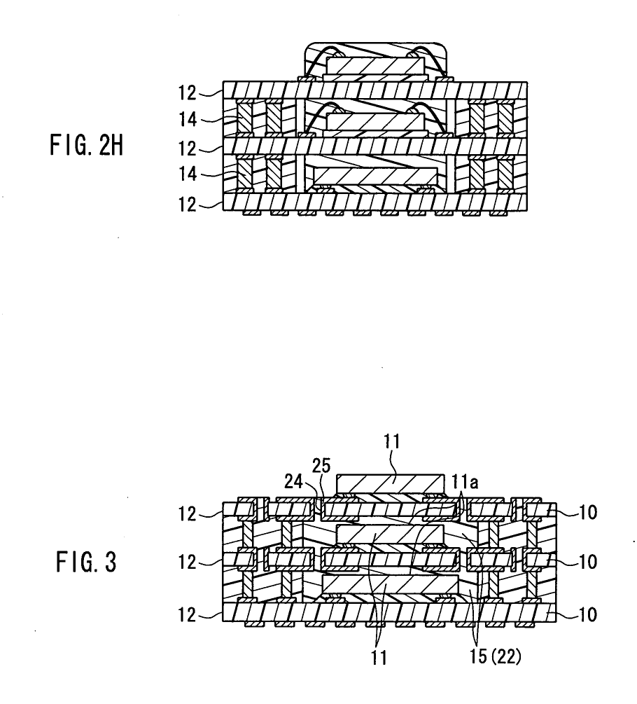

Next, a method for producing the above-mentioned semiconductor device according to Embodiment 1 will be described. FIGS. 2A-2H are cross-sectional views showing process steps in a method for producing a semiconductor device according to Embodiment 1. As shown in FIG. 2A, a semiconductor element 11 is bonded to a substrate 10 with a die-bond agent 18, and furthermore, an electrode 17 on the semiconductor element 11 and an element-mounting electrode 20 are connected to each other with a wire 16 so as to manufacture a circuit board 12.

Subsequently, the semiconductor element 11 is sealed with a low-elastic material 22 as shown in FIG. 2B, thereby manufacturing a semiconductor package 26.

Next, a sheet member 13 of an uncured thermosetting resin composition is prepared as shown in FIG. 2C. As shown in FIG. 2D, an element-containing portion (cavity) 15 is formed in the sheet member 13, and furthermore, through holes 28 are formed as shown in FIG. 2E. Subsequently, a conductor 29 is filled in the through holes 28 as shown in FIG. 2F.

The sheet member 13 as shown in FIG. 2C can be formed by any suitable method selected in accordance with the viscosity of the thermosetting resin composition in use. Specific examples of applicable methods include a doctor-blade method, an extrusion method, a method of using a curtain coater, a method of using a roller coater, and a method of impregnating an uncured thermosetting resin composition in a reinforcer. A doctor-blade method or an extrusion method is used particularly preferably due to the convenience. A solvent can be added to the thermosetting resin composition for adjusting the viscosity as required. Examples of the solvent used for the viscosity adjustment include methylethylketone (MEK), isopropanol, toluene and the like. In a case of adding these solvents, it is preferable that the thermosetting resin composition is shaped into a sheet and subsequently dried to remove the solvent ingredients. The method of drying is not limited particularly as long as the temperature is set lower than the temperature at which the thermosetting resin composition starts curing.

The element-containing portion 15 can be formed by punching with a mold, a laser processor or a punching machine, for example. The through holes 28 can be formed by punching with a carbon dioxide gas laser or a punching machine, for example. The diameter of the through holes 28 can be selected suitably in accordance with the thickness or the like of the sheet member 13, and preferably it is not more than 300 μm, and more preferably, not more than 150 μm. According to this preferred example, the mounting density can be improved remarkably in comparison with a method of connecting circuit boards by using solder balls.

For the conductor 29 to form the via-conductors 14 (see FIG. 1), for example, a mixed paste including a conductive powder and an uncured thermosetting resin can be used. Examples of paste-mixing methods include, for example, a three-roll method, a method of using a planetary mixer and the like. At this time, for example, 30 to 150 volume parts of the thermosetting resin composition are mixed with respect to 100 volume parts of the conductive powder. Furthermore, a curing agent, a curing catalyst, a lubricant, a coupling agent, a surfactant, a retarder thinner, a reactive diluent or the like can be added to the conductor 29.

The method of filling the conductor 29 in the through holes 28 is not limited particularly, and a screen printing method or the like can be used, for example.

The element-containing portion 15 and the through holes 28 as shown in FIGS. 2D and 2E can be formed simultaneously. The order of the process steps shown in FIG. 2C to FIG. 2F can be exchanged. For example, the through holes 28 are formed and then the conductor 29 is filled in the through holes 28, and subsequently the element-containing portion 15 is formed.

Next, as shown in FIG. 2G, a plurality of semiconductor packages 26 and a plurality of sheet members 13 containing the conductor 29 are laminated alternately. As shown in FIG. 2H, the components are integrated with each other by applying heat and pressure, and the plural circuit boards 12 are connected electrically to each other with the via-conductors 14 made of the conductor 29 so as to obtain a semiconductor device according to Embodiment 1. In the semiconductor package 26 positioned at the bottom in FIG. 2G, the semiconductor element 11 is flip-chip mounted through a gold bump 27. An underfill 19 is arranged between the flip-chip mounted semiconductor element 11 and the substrate 10. The method of flip-chip mounting the semiconductor element 11 is not limited particularly, but a well-known flip-chip connection technique can be used. The method of arranging the underfill 19 is not limited particularly, and the examples include a method of thermocompression-bonding a sheet-like underfill 19 at a desired position on the substrate 10, and a method of mounting the semiconductor element 11 on the substrate 10 and then injecting a liquid underfill 19 from space between the substrate 10 and the semiconductor element 11.

The method of applying heat and pressure is not limited particularly, and examples thereof include a method of using a heat press with a mold, and a method of using an autoclave. The temperature and pressure can be determined suitably in accordance with the thermosetting resin composition and the thermosetting resin in the conductor 29 in use, and in general, the temperature is in a range of 140 to 230° C. and the pressure is in a range of 0.3 to 5 MPa.

In FIG. 2G, a sheet member 13 containing a conductor 29 is arranged between a pair of semiconductor packages 26. Alternatively, a plurality of sheet members 13 can be arranged between a pair of semiconductor packages 26. This method is preferred from a viewpoint that, since a distance between the semiconductor packages 26 can be changed without changing the thickness of the sheet members 13, via-conductors 14 with a high aspect ratio can be formed easily.

### EMBODIMENT 2

FIG. 3 is a cross-sectional view showing a semiconductor device according to Embodiment 2 of the present invention. As shown in FIG. 3, in a semiconductor device according to Embodiment 2, all of the semiconductor elements 11 are flip-chip mounted. In the top and intermediate substrates 10 in FIG. 3, through holes 24 for communicating with element-containing portions 15 are formed, and penetration conductor 25 for electrically connecting the wirings formed on both the surfaces of the substrates 10 is formed on the through holes 24. A low-elastic material 22 is filled in the cavities in the element-containing portions 15. Namely, the semiconductor device according to Embodiment 2 has no cavities in the interior. Excepting this, the semiconductor device in this embodiment is similar to the semiconductor device (see FIG. 1) according to the above-mentioned Embodiment 1.

Since the above-mentioned through holes 24 are formed in the semiconductor device according to Embodiment 2, the low-elastic material 22 can be injected from the through holes 24 in the below-mentioned method for producing a semiconductor device. Thereby, it is possible to fill the cavities in the element-containing portions 15 reliably with the low-elastic material 22. Moreover, since the penetration conductor 25 is contained, the mounting density can be increased further.

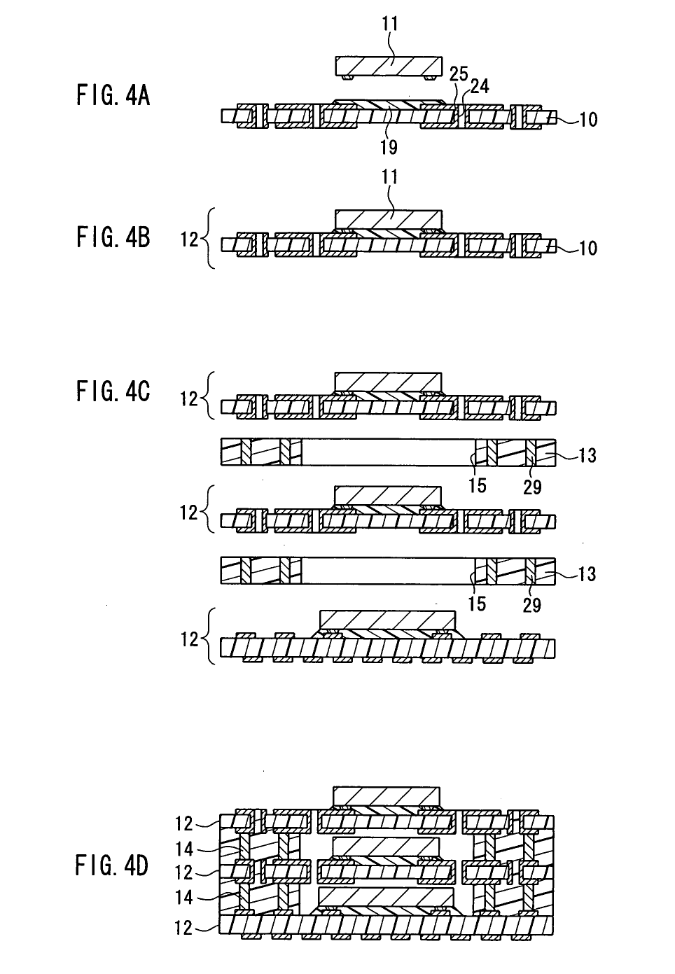

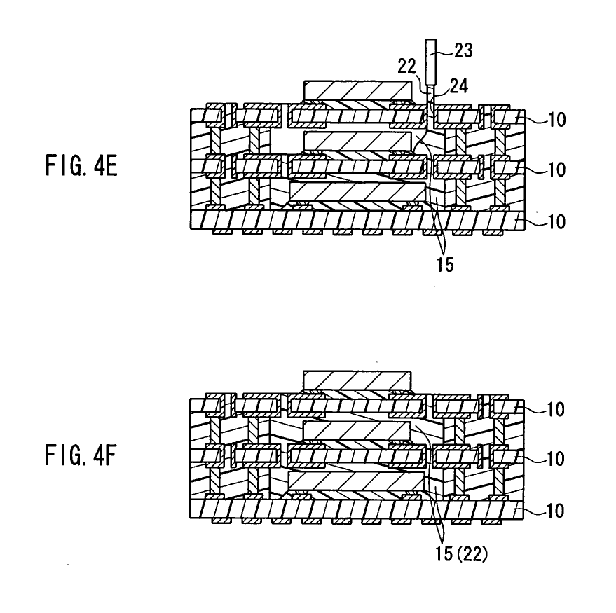

Next, a method for producing a semiconductor device according to Embodiment 2 of the present invention will be described. FIGS. 4A-4F are cross-sectional views showing process steps in a method for producing a semiconductor device according to Embodiment 2. As shown in FIG. 4A, a semiconductor element 11 is flip-chip mounted on a substrate 10 so as to sandwich an underfill 19 arranged on the substrate 10, thereby a circuit board 12 as shown in FIG. 4B is manufactured. Through holes 24 are formed previously in the substrate 10, and provided with penetration conductors 25. The method for forming the through holes 24 is not limited particularly, and a method similar to the method of forming the above-mentioned through holes 28 (see FIG. 2E) can be used, for example. Similarly, the penetration conductor 25 can be formed by a known plating method or the like, without any particular limitations.

Next, as shown in FIG. 4C, a plurality of circuit boards 12 and a plurality of sheet members 13 both formed in the same manner as shown in FIGS. 2C to 2F and having a conductor 29 are laminated alternately. These components are integrated with each other by application of heat and pressure as shown in FIG. 4D, and at the same time, a plurality of circuit boards 12 are connected electrically to each other with via-conductors 14 made of the conductor 29. Neither through holes 24 nor penetration conductors 25 are formed in a circuit board 12 positioned at the bottom in FIG. 4C.

The method of applying heat and pressure is not limited particularly, and the examples include a method of using a heat press with a mold, and a method of using an autoclave. The temperature and pressure can be determined suitably in accordance with the thermosetting resin composition and the thermosetting resin in the conductor 29 in use, and in general, the temperature is in a range of 140 to 230° C. and the pressure is 0.3 in a range of to 5 MPa.

Next, as shown in FIG. 4E, the low-elastic material 22 is injected from the through holes 24 into the element-containing portion 15 by using an injector 23. Later, as shown in FIG. 4F, the low-elastic material 22 is cured, and thus a semiconductor device according to Embodiment 2 is obtained.

For the injector 23, for example, a dispenser can be used. In an alternative method, the injector 23 is not used, but a semiconductor device in a state as shown in FIG. 4D is dipped in the low-elastic material 22, and subjected repeatedly to reduction-application of pressure so as to fill the low-elastic material 22.

Though the low-elastic material 22 can be identical to that as described in Embodiment 1, preferably it is a liquid at the time of injection as shown in FIG. 4E and is solidified after a curing as shown in FIG. 4F. For curing, an ordinary thermosetting method can be used.

According to the present embodiment, since the cavity in the element-containing portion 15 is filled with the low-elastic material 22, deformation caused by presence of a cavity can be prevented, and thus, a semiconductor device having an excellent mounting reliability can be provided.

### EMBODIMENT 3

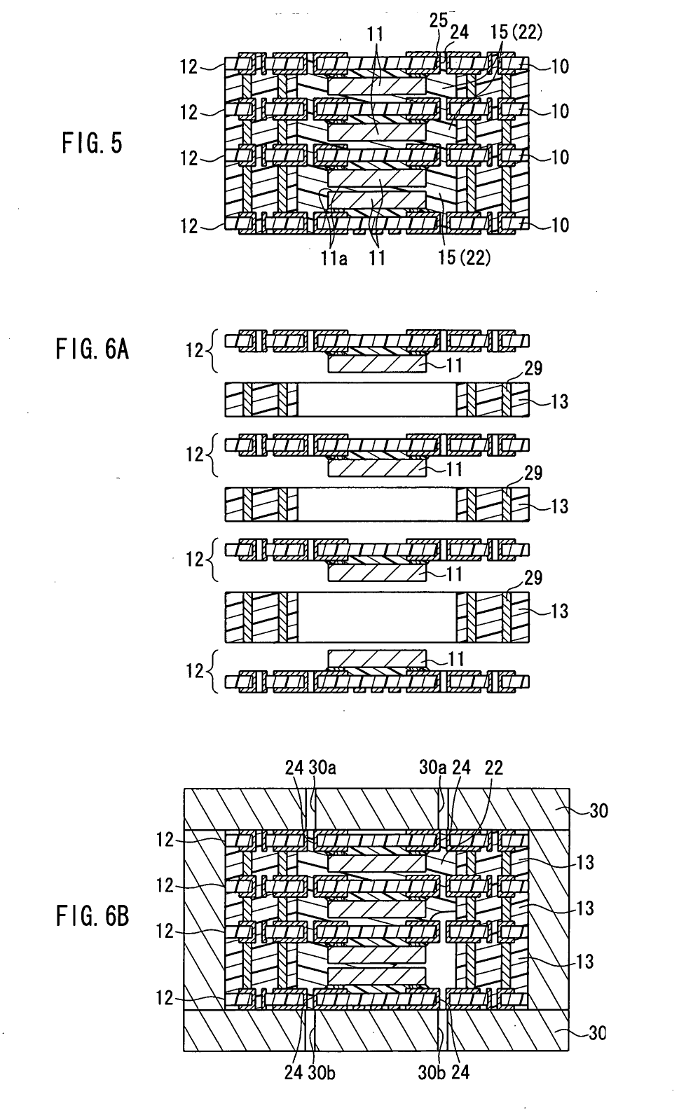

FIG. 5 is a cross-sectional view showing a semiconductor device according to Embodiment 3 of the present invention. As shown in FIG. 5, in a semiconductor device according to Embodiment 3, four circuit boards 12 are laminated. Through holes 24 are formed in all of the substrates 10 and provided with penetration conductors 25. Furthermore, on each of the bottom substrate 10 and a substrate 10 second from the bottom, a semiconductor element 11 to be contained in the element-containing portion 15 is mounted. The pair of semiconductor elements 11 are contained facing each other in the element-containing portion 15. A low-elastic material 22 is filled in the cavity in the element-containing portion 15 including space between surfaces 11a, 11a of the semiconductor elements 11, 11. Excepting these characteristics, the semiconductor device is similar to the above-mentioned semiconductor device (see FIG. 3) according to Embodiment 2. Therefore, the semiconductor device according to Embodiment 3 can provide effects as those of the semiconductor device according to Embodiment 2.

Since the pair of semiconductor elements 11, 11 are contained facing each other in an element-containing portion 15 in the semiconductor device according to Embodiment 3, the surface area of the semiconductor device can be reduced easily.

Next, a method for producing a semiconductor device according to Embodiment 3 will be described below. FIGS. 6A and 6B are cross-sectional views showing process steps for a method for producing a semiconductor device according to Embodiment 3.

A plurality of circuit boards 12 are prepared in a method similar to the method as shown in FIGS. 4A, 4B, and a plurality of sheet members 13 containing a conductor 29 are prepared in a method similar to the method as shown in FIGS. 2C to 2F. The thus obtained circuit boards 12 and the sheet members 13 are laminated alternately as shown in FIG. 6A.

Next, as shown in FIG. 6B, these components are arranged in a mold 30 for clamping. The mold 30 has inlets 30a and outlets 30b at positions corresponding to the through holes 24 of the circuit boards 12. The mold 30 is heated under pressure, and at the same time, a low-elastic material 22 is injected from the inlets 30a so as to cure a thermosetting resin composition of the sheet members 13 and the low-elastic material 22 simultaneously for integration, and also to connect the circuit boards 12 electrically to each other, and thereby a semiconductor device according to Embodiment 3 was obtained.

When injecting the low-elastic material 22 from the inlets 30a of the mold 30, the pressure in the mold 30 is reduced preferably by suction from the outlets 30b.

According to the producing method, since the thermosetting resin composition can be cured and the low-elastic material 22 can be filled and cured in a process step, a semiconductor device of the present invention can be obtained in a simple method.

### EMBODIMENT 4

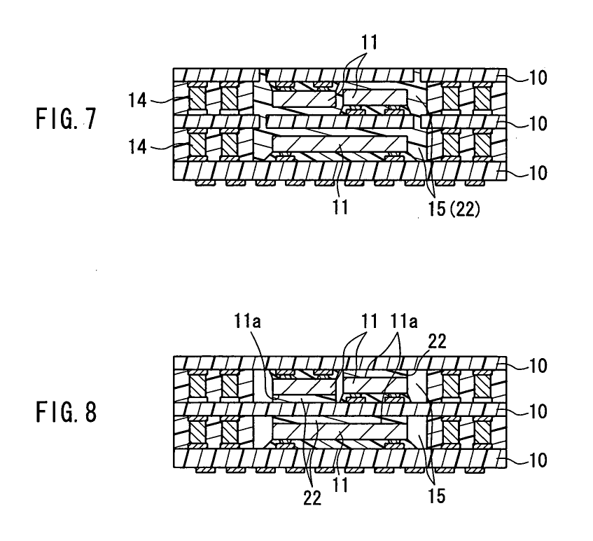

FIG. 7 is a cross-sectional view showing a semiconductor device according to Embodiment 4 of the present invention. As shown in FIG. 7, in a semiconductor device according to Embodiment 4, at least one semiconductor element 11 is mounted on each of a pair of opposing substrates 10. Since a plurality of semiconductor elements 11 can be contained in an element-containing portion 15 in the semiconductor device according to Embodiment 4, the thickness of the semiconductor device can be decreased. When plural semiconductor elements 11 varied in size are contained, surface areas of the substrates 10 can be used efficiently, which serves to decrease the dead space that will not allow either formation of a via-conductor 14 or mounting of the semiconductor element 11.

The semiconductor device according to Embodiment 4 can be produced by the method as shown in FIGS. 4A-4F.

### EMBODIMENT 5

FIG. 8 is a cross-sectional view showing a semiconductor device according to Embodiment 5 of the present invention. As shown in FIG. 8, in a semiconductor device according to Embodiment 5, a low-elastic material 22 is filled only in the space between upper surfaces 11a of semiconductor elements 11 and substrates 10.

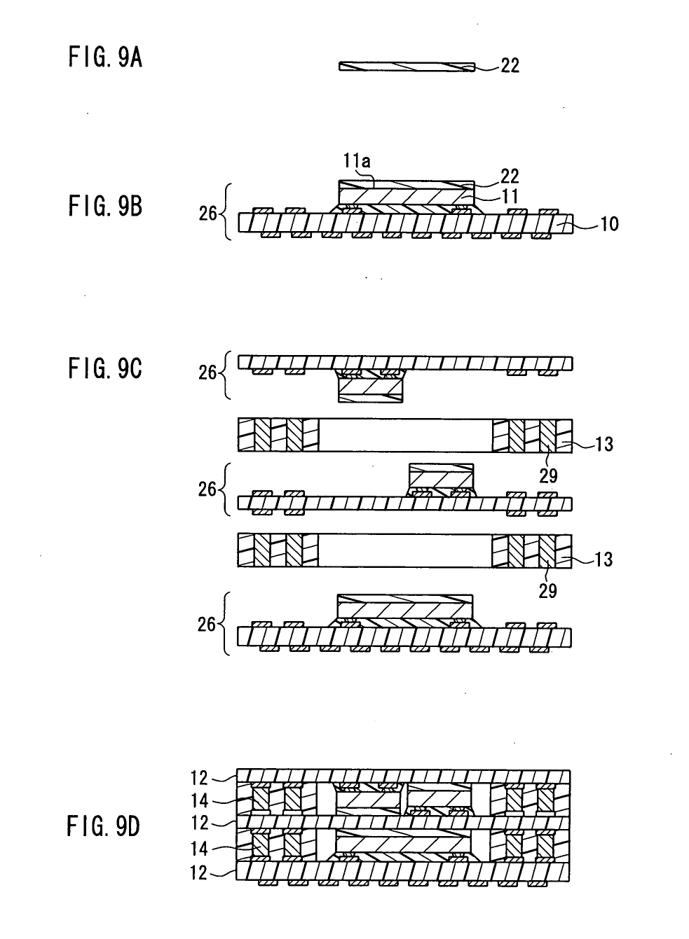

Next, a method for producing the above-mentioned semiconductor device according to Embodiment 5 will be described. FIGS. 9A-9D are cross-sectional views showing process steps in a method for producing the semiconductor device according to Embodiment 5.

As shown in FIG. 9A, a low-elastic material 22 is solidified and shaped into a sheet. For solidifying the low-elastic material 22, thermosetting, photo-curing, curing through a moisture-absorbing action and the like can be used. The method of shaping the low-elastic material 22 into a sheet is not limited particularly, and a method similar to the above-mentioned method for shaping the sheet member 13 can be used.

Next, as shown in FIG. 9B, the sheet-like low-elastic material 22 is bonded to an upper surface 11a of a semiconductor element 11 that is flip-chip mounted on a substrate 10, thereby a semiconductor package 26 is manufactured.

Next, as shown in FIG. 9C, a plurality of semiconductor packages 26 and a plurality of sheet members 13 formed in a method similar to the method as shown in FIGS. 2C-2F and containing a conductor 29 are laminated, and integrated with each other by application of heat and pressure, and at the same time, the circuit boards 12 are connected electrically to each other with via-conductors 14, thereby a semiconductor device (FIG. 9D) according to Embodiment 5 is obtained.

According to the producing method, since the low-elastic material 22 can be filled in the space between an upper surface 11a of a semiconductor element 11 and the substrate 10 without formation of any through holes, the semiconductor device of the present invention can be obtained in a simpler manner.

In the producing method, the sheet-like low-elastic material 22 is bonded to the upper surface 11a of the semiconductor element 11. Alternatively, the low-elastic material 22 can be bonded onto the substrate 10 opposing the semiconductor element 11. In the step as shown in FIG. 9A, the sheet-like low-elastic material 22 is not necessarily cured as long as it can retain the shape, since the low-elastic material 22 can be cured in the subsequent step of lamination-integration.

### EMBODIMENT 6

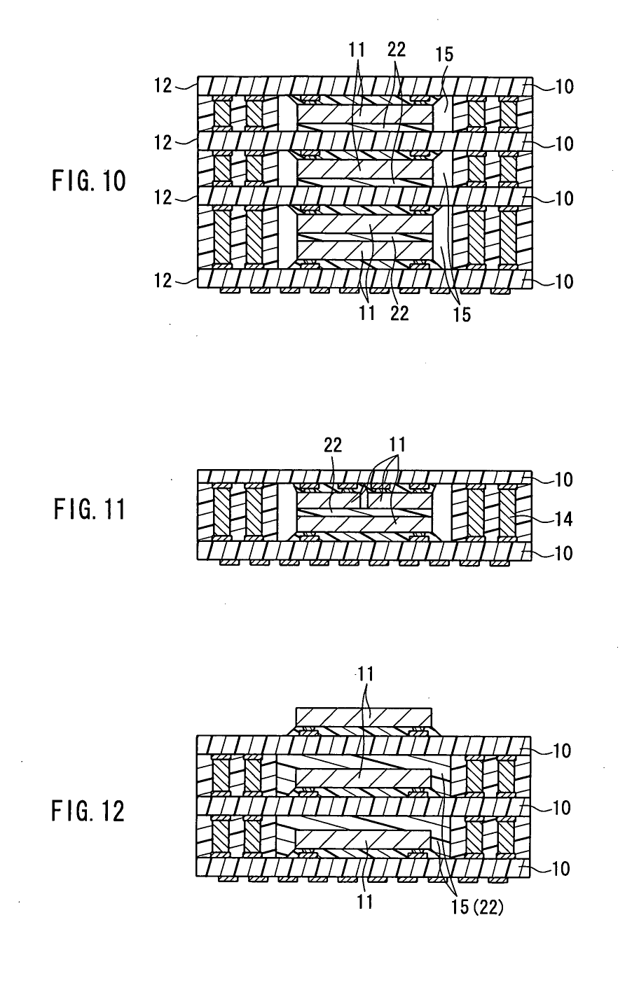

FIG. 10 is a cross-sectional view showing a semiconductor device according to Embodiment 6 of the present invention. As shown in FIG. 10, in a semiconductor device according to Embodiment 6, four circuit boards 12 are laminated. A semiconductor element 11 to be contained in an element-containing portion 15 is mounted on each of the bottom substrate 10 and the second bottom substrate 10 in FIG. 10. The pair of semiconductor elements 11,11 are contained facing each other in the element-containing portion 15. A low-elastic material 22 is filled in the space between the semiconductor elements 11,11. A semiconductor element 11 to be contained in an element-containing portion 15 is mounted on each of the top substrate 10 and the second top substrate 10 in FIG. 10, and a low-elastic material 22 is filled in the space between the semiconductor element 11 and the substrate 10 opposing the upper surface of the semiconductor element 11. Even when thin substrates 10 or thin semiconductor elements 11 are used in the semiconductor device according to Embodiment 6, the low-elastic material 22 suppresses warping and deformation, and thus the mounting reliability is improved. Moreover, since the pair of semiconductor elements 11, 11 are contained facing each other in the element-containing portion 15, the surface area of the semiconductor device can be reduced easily.

The semiconductor device according to Embodiment 6 can be manufactured by a method as explained by referring to FIGS. 9A-9D.

### EMBODIMENT 7

FIG. 11 is a cross-sectional view showing a semiconductor device according to Embodiment 7 of the present invention. As shown in FIG. 11, in a semiconductor device according to Embodiment 7, a plurality of semiconductor elements 11 facing each other are flip-chip mounted on each of a pair of opposing substrates 10, and a low-elastic material 22 is filled in the space between upper surfaces of the semiconductor elements 11. Furthermore, a plurality of semiconductor elements 11 are mounted on a surface of a top substrate 10. The semiconductor device according to Embodiment 7 can provide effects similar to those of the semiconductor device according to Embodiment 6. In addition to that, when semiconductor elements 11 varied in size are mounted, it is possible to decrease the dead space that does not allow either formation of a via-conductor 14 or mounting of a semiconductor element 11. The semiconductor device according to Embodiment 7 can be manufactured by a method similar to the method as explained by referring to FIGS. 9A-9D.

### EMBODIMENT 8

FIG. 12 is a cross-sectional view showing a semiconductor device according to Embodiment 8 of the present invention. As shown in FIG. 12, a semiconductor device according to Embodiment 8 is the same as the semiconductor device (see FIG. 3) according to Embodiment 2, except that neither through holes 24 nor penetration conductor 25 are formed. Similar to the semiconductor device of Embodiment 2, the cavity in the element-containing portion 15 of the semiconductor device in Embodiment 8 is filled with the low-elastic material 22, and thus deformation caused by the cavities can be prevented, and a semiconductor device with excellent mounting reliability can be provided.

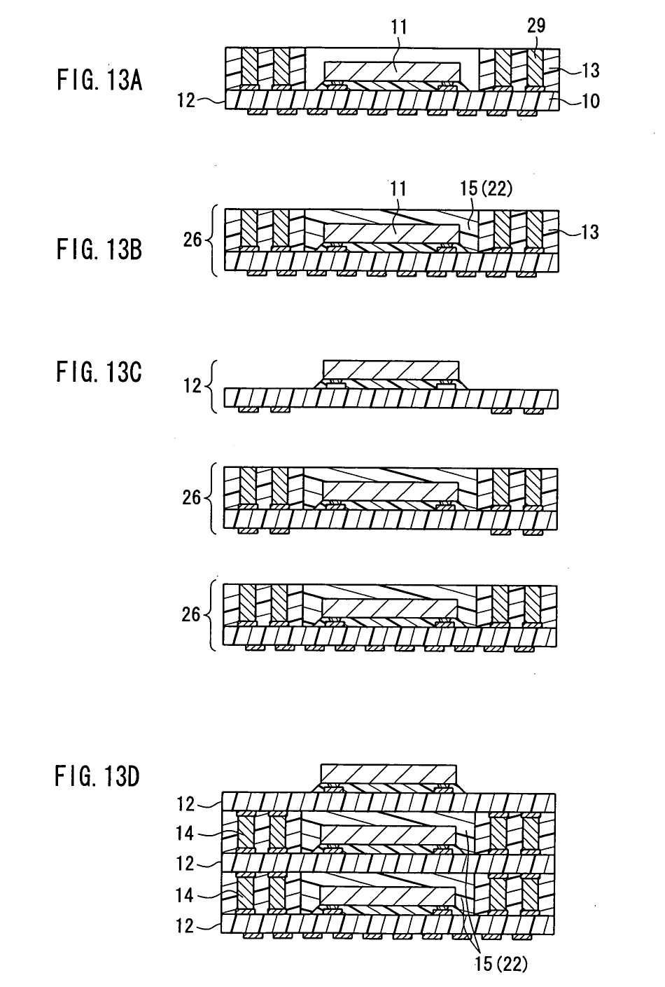

Next, a method for producing the above-mentioned semiconductor device according to Embodiment 8 will be described. FIGS. 13A-13D are cross-sectional views showing process steps in a method for producing the above-mentioned semiconductor device according to Embodiment 8.

First, a circuit board 12 prepared by mounting a semiconductor element 11 on a substrate 10, and a sheet member 13 containing a conductor 29, are laid as shown in FIG. 13A. Next, as shown in FIG. 13B, a low-elastic material 22 is injected into an element-containing portion 15 formed in the sheet member 13, thereby manufacturing a semiconductor package 26. Next, as shown in FIG. 13C, a plurality of semiconductor packages 26 are laminated and further a circuit board 12 is laminated on the top. These components are integrated with each other by application of heat and pressure, and at the same time, the circuit boards 12 are connected electrically to each other with via-conductors 14, and further the low-elastic material 22 is cured. Thereby a semiconductor device (FIG. 13D) according to Embodiment 8 is obtained.

In the producing method, after a step as shown in FIG. 13B, the low-elastic material 22 can be cured or softly cured in order to improve the workability of the semiconductor packages 26. In such a case, the low-elastic material 22 must be cured or softly cured under a condition that avoids curing of the thermosetting resin composition of the sheet members 13. Examples of the methods include a method of heat-processing at a temperature lower than the curing temperature of the thermosetting resin composition, a method of photo-curing, and a method of curing by moisture absorption.

It is preferable in the above-mentioned producing method that evacuation is carried out after the step of FIG. 13B so as to remove air bubbles contained in the low-elastic material 22.

According to the producing method, since it is possible to fill the low-elastic material 22 without forming a through hole, a semiconductor device of the present invention can be obtained in a simpler producing method.

### EMBODIMENT 9

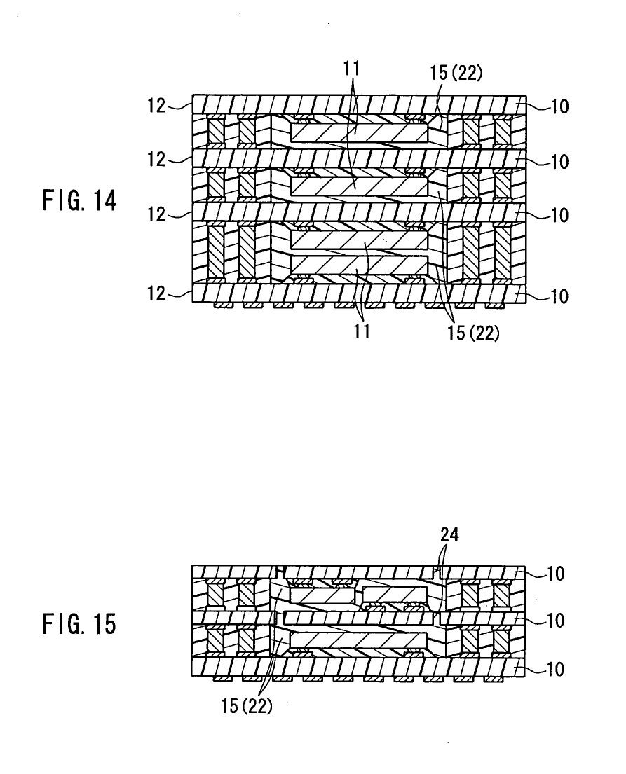

FIG. 14 is a cross-sectional view showing a semiconductor device according to Embodiment 9 of the present invention. The semiconductor device according to Embodiment 9 is a modification of the semiconductor device (see FIG. 12) according to Embodiment 8. As shown in FIG. 14, in a semiconductor device according to Embodiment 9, four circuit boards 12 are laminated. A semiconductor element 11 to be contained in an element-containing portion 15 is mounted on each of the bottom substrate 10 and the second bottom substrate 10 in FIG. 14. The pair of semiconductor elements 11,11 are contained facing each other in the element-containing portion 15. The semiconductor device according to Embodiment 9 can be manufactured by the same method as the method explained by referring to FIGS. 13A-13D.

### EMBODIMENT 10

FIG. 15 is a cross-sectional view showing a semiconductor device according to Embodiment 10 of the present invention. The semiconductor device according to Embodiment 10 is a modification of the semiconductor device (see FIG. 8) according to Embodiment 5. As shown in FIG. 15, in a semiconductor device according to Embodiment 10, through holes 24 are formed in the top substrate 10 and the intermediate substrate 10 in FIG. 15. The semiconductor device according to Embodiment 10 can be manufactured by the same method as the method explained by referring to FIGS. 4A-4F.

### EXAMPLES

Examples of the present invention will be described below. The present invention will not be limited to the following examples.

(Mounting Reliability)

In Example 1, the above-mentioned semiconductor device (see FIG. 3) according to Embodiment 2 was manufactured by a method as shown in FIGS. 4A-4F. The materials used in Example 1 and details of the manufacturing method will be explained below with a reference to FIGS. 4A-4F.

For each of the substrates 10, a glass-epoxy substrate 0.07 mm thick was used. Through holes 24 (diameter: 300 μm) were formed in the vicinity of the element-mounting part in the substrate 10, and the through holes 24 were plated to form penetration conductors 25. Semiconductor elements 11 in use were silicon semiconductor elements for a connection test, each being 6 mm×6 mm and 100 μm in thickness and electrodes are formed at 120 μm pitch on the periphery. A gold wire 25 μm in diameter was joined onto the electrodes of this semiconductor element 11 by using ultrasonic, thereby forming a bump. In formation of the bump, a bump bonder (STB-2 by Matsushita Electric Industrial Co., Ltd.) was used.

For an underfill 19, an epoxy resin sheet (produced by Sony Chemical) 50 μm in thickness and containing a silica filler was prepared. This was cut to a size substantially the same as the semiconductor element 11, and temporarily bonded onto the substrate 10 as shown in FIG. 4A. Subsequently, electrodes of the semiconductor element 11 and electrodes on the substrate 10 were positioned each other, and the semiconductor element 11 was mounted on the substrate 10, applied with a pressure of 3 MPa under an atmosphere of 200° C. so as to cure the underfill 19, and thus the circuit board 12 as shown in FIG. 4B was manufactured.

A solid prepared by blending 80 mass % of a melt silica powder and 20 mass % of epoxy resin (containing a curing agent) and methyethylketone. (MEK) as a solvent were kneaded in a planetary mixer. The mixture ratio of the solid to the solvent (mass ratio) was 10:1. This mixture was applied onto a carrier film of polyethylene terephthalate by a doctor-blade method. Later, the MEK was evaporated to manufacture a sheet member 13 (thickness: 100 μm).

This sheet member 13 was processed with a punching machine (produced by UHT) so as to form an element-containing portion 15 and through holes 28 (see FIG. 2E). Then, a conductive paste was manufactured by kneading 87 mass % of a silver-coated copper powder and 13 mass % of epoxy resin (containing a curing agent) by using a three-roll mixer. This conductive paste was filled in the through holes 28 by a printing method, and thereby a sheet member 13 containing the conductor 29 (conductive paste) as shown in FIG. 4C was manufactured.

Next, as shown in FIG. 4C, three circuit boards 12 and two sheet members 13 were laminated alternately and applied with heat and pressure in a mold for 15 minutes under a condition of temperature: 200° C. and pressure: 2 MPa. At the same time, the conductor 29 (conductive paste) was cured to form via-conductors 14 so as to connect electrically the circuit boards 12 (FIG. 4D).

Next, a silicone resin (TSE3051 produced by Toshiba GE silicone) as a low-elastic material 22 was injected from the through holes 24 into the element-containing portion 15 as shown in FIG. 4E. For the injector 23, a dispenser (a production of Musashi Engineering) was used. Later, evacuation was carried out in a vacuum dryer so as to remove air bubbles remaining in the low-elastic material 22, and further a heat treatment was carried out for two hours at 140° C. so as to cure the low-elastic material 22. Thereby a semiconductor device of Example 1 as shown in FIG. 4F was manufactured. The semiconductor device was 0.85 mm in thickness.

For a comparative example, a semiconductor device was manufactured by the same method as in the above-mentioned Example 1 except that the low-elastic material 22 to be injected into the element-containing portion 15 was replaced with a thermosetting resin composition for composing the sheet member 13.

For examining the mounting reliability of the two kinds of semiconductor devices, respectively 10 semiconductor devices were placed for 168 hours in a thermo-hygrostat vessel of 85° C., 60% RH(RH denotes relative humidity), which were then subjected to a reflow at a peak temperature of 250° C. so as to measure resistance values at semiconductor connecting portions. The results show that no conduction failure occurred in any of the ten semiconductor devices of Example 1, while six of ten samples experienced conduction failures of the semiconductor devices of the comparative example.

The thermosetting resin composition of the sheet member 13 and the low-elastic material 22 (silicone resin) were heated respectively at 200° C. in a flat press so as to shape into plates, and the elastic moduli were measured by using a dynamic viscoelasticity measuring instrument (DMS210 produced by Seiko Instrument). The results show that at 25° C. an elastic modulus of the thermosetting resin composition was 8 GPa, while an elastic modulus of the low-elastic material 22 was 50 GPa.

The result shows that the mounting reliability of a semiconductor device is improved by filling a low-elastic material 22 whose elastic modulus is lower than the elastic modulus of the thermosetting resin composition composing the sheet member 13 in the space between the semiconductor element 11 and the substrate 10 opposing the upper surface of the semiconductor element 11

(Heat Dissipation)

A semiconductor element 11 was mounted on a substrate 10 in the same manner as explained in Example 1. A semiconductor element 11 to be mounted on the intermediate substrate 10 had a built-in 200 Ω resistor. Furthermore, a thermocouple was bonded onto the upper surfaces of the semiconductor elements 11 and electrodes of the thermocouple were taken out from the through holes 24. In this state, the respective layers were laminated in the same manner as in Example 1 so as to manufacture a semiconductor device of Example 2. A semiconductor device according to Example 3 was produced in the same manner as Example 2 except that the low-elastic material 22 was prepared by adding to a silicone resin (TSE3051 produced by Toshiba GE silicone) 40 mass % of an alumina powder (average particle diameter: 12 μm) as a thermo-conductive filler.

The semiconductor devices of Examples 2 and 3 were subjected to electric power of 2 W for 10 minutes, and then the temperature at the upper parts of the built-in semiconductor elements 11 in each of the semiconductor devices was measured by using the thermocouple bonded to the semiconductor elements 11. The result shows that the temperature of the semiconductor device in Example 2 was 82° C., and the temperature of the semiconductor device in Example 3 was 73° C. The result shows that heat dissipation is improved when a thermo-conductive filler is added to the low-elastic material 22, and this will improve the effect of suppressing the temperature rise in the semiconductor elements 11.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A semiconductor device having a plurality of circuit boards comprising substrates and semiconductor elements mounted on the substrates, the circuit boards being bonded to each other through sheet members of a thermosetting resin composition, wherein
the plural circuit boards are connected electrically to each other by via-conductors penetrating the sheet members,
the semiconductor elements arranged between the substrates are contained in element-containing portions formed in the sheet members, and
a low-elastic material whose elastic modulus is lower than the elastic modulus of the thermosetting resin composition is filled in a space between semiconductor elements contained in the element-containing portions and the substrates opposing surfaces opposite to the mounting surfaces of the semiconductor elements.

2. The semiconductor device according to claim 1, wherein the semiconductor elements in the element-containing portions are sealed with the low-elastic material.

3. The semiconductor device according to claim 1, wherein cavities in the element-containing portions are filled with the low-elastic material.

4. The semiconductor device according to claim 1, wherein at least one of the semiconductor elements to be contained in one of the element-containing portions is mounted on each of the two substrates covering the element-containing portion.

5. The semiconductor device according to claim 1, wherein at least one of the semiconductor elements is flip-chip mounted on the substrate.

6. The semiconductor device according to claim 1, wherein the low-elastic material contains a moisture-absorbing filler.

7. The semiconductor device according to claim 1, wherein the low-elastic material contains a thermo-conductive filler.

8. The semiconductor device according to claim 1, wherein the low-elastic material has an elastic modulus of 1 MPa to 1000 MPa at 25° C.

9. The semiconductor device according to claim 1, wherein through holes are formed in the vicinity of an area of the substrate for mounting the semiconductor elements, and
the through holes communicate with the element-containing portions.

10. The semiconductor device according to claim 9, wherein penetration conductors for electrically connecting wirings formed on both surfaces of the substrate are formed on the inner surfaces of the through holes.

11. The semiconductor device according to claim 1, wherein the semiconductor elements are flip-chip mounted on a surface of a bottom substrate at the element-containing portion side,
the semiconductor device further comprises an external-connection electrode formed on a surface of the substrate opposite to the element-containing portion side, and
the other semiconductor element is mounted on the other substrate by wire-bonding.

12. The semiconductor device according to claim 1, wherein the thermosetting resin composition contains inorganic filler in an mount of 70 mass % to 95 mass %.

13. The semiconductor device according to claim 1, wherein the thermosetting resin composition contains a reinforcer in an amount of 15 mass % to 50 mass %.

14. A semiconductor device having a plurality of circuit boards comprising substrates and semiconductor elements mounted on the substrates, the circuit boards being bonded to each other through sheet members of a thermosetting resin composition, wherein
the plural circuit boards are connected electrically to each other by via-conductors penetrating the sheet members,
the semiconductor elements arranged between the substrates are contained in element-containing portions formed on the sheet members,
at least one of the semiconductor elements to be contained in one of the element-containing portions is mounted on each of the two substrates covering the element-containing portion,
at least one pair of the semiconductor elements are contained facing each other in the element-containing portion, and
a low-elastic material whose elastic modulus is lower than the elastic modulus of the thermosetting resin composition is filled in the space between the surfaces of the pair of the semiconductor elements.

15. The semiconductor device according to claim 14, wherein a cavity in the element-containing portion is filled with the low elastic modulus material.

16. The semiconductor device according to claim 14, wherein the low-elastic material contains a moisture-absorbing filler.

17. The semiconductor device according to claim 14, wherein the low-elastic material contains a thermo-conductive filler.

18. The semiconductor device according to claim 14, wherein the low-elastic material has an elastic modulus of 1 MPa to 1000 MPa at 25° C.

19. A method for producing a semiconductor device, the method comprising:
mounting semiconductor elements on substrates so as to form circuit boards,
forming, on sheet members comprising an uncured thermosetting resin composition, element-containing portions for containing the semiconductor elements and through holes to be filled with a conductor,
filling the through holes with a conductor,
positioning and laminating the circuit boards and the sheet members alternately, and subsequently applying heat and pressure while injecting a low-elastic material into the element-containing portions, where the elastic modulus of the low-elastic material is lower than the elastic modulus of the thermosetting resin composition, so that the thermosetting resin composition and the low-elastic material are cured simultaneously and integrated, and the plural circuit boards are connected electrically.

20. The method for producing a semiconductor device according to claim 19, wherein the method further comprising:
forming through holes in the circuit boards in the vicinity of areas for mounting the semiconductor elements before laminating the circuit boards and the sheet members, and
injecting the low-elastic material into the element-containing portions from the through holes.
